(19) United States
(12) Patent Application Publication
(10) Pub. No.: US 2020/0071825 A1
(43) Pub. Date: Mar. 5, 2020

(54) Methods Of Depositing Metal Carbide Films

(71) Applicant: Applied Materials, Inc., Santa Clara, CA (US)

(72) Inventors: Lakmal C. Kalutarage, San Jose, CA (US); Jeffrey W. Anthis, San Jose, CA (US); Mark Saly, Santa Clara, CA (US); David Thompson, San Jose, CA (US); Yongjing Lin, San Jose, CA (US); Shih Chung Chen, Cupertino, CA (US)

(21) Appl. No.: 16/550,523

(22) Filed: Aug. 26, 2019

Related U.S. Application Data
(60) Provisional application No. 62/723,596, filed on Aug. 28, 2018.

(51) Int. Cl. C23C 16/455; C23C 16/32; C23C 28/00

(52) U.S. Cl. CPC C23C 16/45529; C23C 28/34; C23C 16/32

(57) ABSTRACT

Methods of depositing a metal carbide film by exposing a substrate surface to a halide precursor and an aluminum reactant are described. The halide precursor comprises a compound of general formula (I) MX_{y}Rₙ, wherein M is a metal, X is a halogen selected from Cl, Br, F or I, y is from 1 to 6, R is selected from alkyl, CO, and cyclopentadienyl, and n is from 0 to 6. The aluminum reactant comprises a compound of general formula (II) Al(CH₂AR¹R²R³)₃, wherein A is C, Si, or Ge, each of R¹, R², and R³ is independently alkyl or comprises substantially no β-hydrogen.

### CROSS-REFERENCE TO RELATED APPLICATIONS

This application claims priority to U.S. Provisional Application No. 62/723,596, filed Aug. 28, 2018, the entire disclosure of which is hereby incorporated by reference herein.

### TECHNICAL FIELD

Embodiments of the present disclosure generally relate to film deposition. More particularly, embodiments of the present disclosure related to the deposition of metal carbide films that are substantially free of aluminum.

### BACKGROUND

Deposition of thin films on a substrate surface is an important process in a variety of industries including semiconductor processing, diffusion barrier coatings, and dielectrics for magnetic read/write heads. In the semiconductor industry, in particular, miniaturization requires atomic level control of thin film deposition to produce conformal coatings on high aspect structures.

One method for deposition of thin films is atomic layer deposition (ALD). Most ALD processes are based on binary reaction sequences, where each of the two surface reactions occurs sequentially. Because the surface reactions are sequential, the two gas phase reactants are not in contact, and possible gas phase reactions that may form and deposit particles are limited. While ALD tends to result in more conformal films than traditional chemical vapor deposition (CVD), prior art processes for ALD have been most effective for deposition of metal oxide and metal nitride films. Although a few processes have been developed that are effective for deposition of elemental ruthenium and other late transition metals, in general ALD processes for deposition of pure metal have not been sufficiently successful to be adopted commercially.

Work function metal is of great interest in metal oxide semi-conductor (MOS) transistor applications. Metal films such as tantalum carbide (TaC), titanium carbide (TiC), titanium aluminum carbide (TiAIC), and titanium aluminum (TiAl) have been evaluated as candidates for n-metals (work function metals) in MOS transistors. In future nodes, the presence of aluminum in work function metal films is unfavorable because aluminum can migrate to other film stacks, leading to complications. Accordingly, there is a need for depositing metal carbide films that are free of aluminum.

### SUMMARY

One or more embodiments of the disclosure are directed to a method of depositing a film. In one or more embodiments, the method comprises exposing at least a portion of a substrate surface to a first halide precursor comprising a compound of general formula (I): MX_{y}Rₙ (I), wherein M is a metal, X is a halogen selected from Cl, Br, F or I, y is from 1 to 6, R is selected from alkyl, CO, cyclopentadienyl, amidinate, diazadiene, or amidate, and n is from 0 to 6. At least a portion of the substrate surface is then exposed to an aluminum reactant comprising a compound of general formula (II): Al(CH₂AR¹R²R³)₃ (II), wherein A is C, Si, or Ge, each of R¹, R², and R³ is independently alkyl or comprises substantially no p-hydrogen. A metal carbide film is deposited on the substrate surface, the metal carbide film substantially free of aluminum.

In one or more embodiments, a method of depositing a film comprises: positioning a substrate in a processing chamber. At least a portion of the substrate surface is exposed to a first halide precursor comprising a compound of general formula (I): MX_{y}Rₙ (I), wherein M is a metal, X is a halogen selected from Cl, Br, F or I, y is from 1 to 6, R is selected from alkyl, CO, cyclopentadienyl, amidinate, diazadiene, or amidate, and n is from 0 to 6. The processing chamber is then purged of the first halide precursor. At least a portion of the substrate surface is then exposed to an aluminum reactant comprising a compound of general formula (II): Al(CH₂AR¹R²R³)₃ (II), wherein A is C, Si, or Ge, each of R¹, R², and R³ is independently alkyl or comprises substantially no β-hydrogen. The processing chamber is then purged of the aluminum reactant. A metal carbide film is deposited on the substrate surface, the metal carbide film substantially free of aluminum (Al)

In one or more embodiments, a method of depositing a film comprises exposing at least a portion of a substrate surface to a first halide precursor comprising a compound having the general formula (IA): M¹X_{y}Rₙ, (IA), wherein M¹ is a metal, X is a halogen selected from Cl, Br, F or I, y is from 1 to 6, R is selected from alkyl, CO, cyclopentadienyl, amidinate, diazadiene, or amidate, and n is from 0 to 6. At least a portion of the substrate surface is then exposed to a second halide precursor comprising a compound having the general formula (IB): M²X_{y}Rₙ (IB), wherein M² is a metal, X is a halogen selected from Cl, Br, F or I, y is from 1 to 6, R is selected from alkyl, CO, cyclopentadienyl, amidinate, diazadiene, or amidate, and n is from 0 to 6. At least a portion of the substrate surface is then exposed to an aluminum reactant comprising a compound of general formula (II): Al(CH₂AR¹R²R³)₃ (II) wherein A is C, Si, or Ge, each of R¹, R², and R³ is independently alkyl or comprises substantially no β-hydrogen. A mixed-metal carbide film is deposited on the substrate surface, the mixed-metal carbide film substantially free of aluminum.

One or more embodiments of the disclosure are directed to a gate stack of a MOS transistor. In one or more embodiments, a gate stack comprises: a high-78 dielectric layer on a substrate; a titanium nitride layer on the high-κ dielectric layer; a work function layer on the titanium nitride layer; and a second titanium nitride layer on the work-function layer. The work-function layer comprises a metal carbide film substantially free of aluminum and having less than 50% total metal content on an atomic basis.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a flow process diagram of a method of forming a metal carbide film according to embodiments described herein; and

FIG. 2 depicts a gate stack in accordance with one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Embodiments of the disclosure are directed to a halogen removal pathway to deposit metal carbide films. More specifically, embodiments of the disclosure are directed to the use of alkyl aluminum reactants that do not have β-hydrogen groups for the deposition of metal carbide films. β-hydride elimination is a decomposition mechanism in organometallic chemistry and can lead to low thermal stability and potential isomerization of the precursors. (Crabtree, R. H. The Organometallic Chemistry of the Transition Metals, Second Edition, John Wiley & Sons 1994.) Scheme (I) is an example of β-hydride elimination from triethylaluminum.

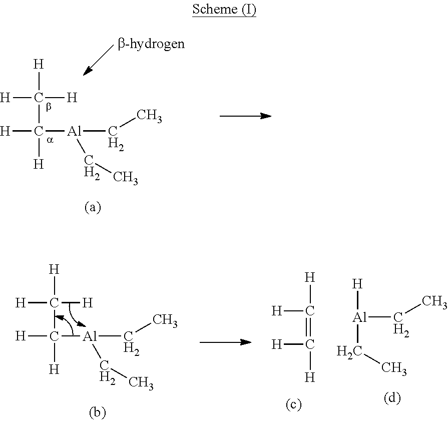

Embodiments of the disclosure are directed to compounds and uses of the compounds that are less likely to decompose or isomerize inside the ampoule leading to process drift. Embodiments of the disclosure are directed to compounds, and uses, that will allow depositions requiring aluminum (Al) precursors to run at higher temperature. In some embodiments, the aluminum (Al) precursors permit depositions to be run at low temperatures, as well.

As used in this specification and the appended claims, the term “substrate” and “wafer” are used interchangeably, both referring to a surface, or portion of a surface, upon which a process acts. Those skilled in the art will understand that reference to a substrate can also refer to only a portion of the substrate, unless the context clearly indicates otherwise. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive in an atomic layer deposition process. For example, a first “reactive gas” may simply adsorb onto the surface of a substrate and be available for further chemical reaction with a second reactive gas.

A “substrate” as used herein, refers to any substrate or material surface formed on a substrate upon which film processing is performed during a fabrication process. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure any of the film processing steps disclosed may also be performed on an underlayer formed on the substrate as disclosed in more detail below, and the term “substrate surface” is intended to include such underlayer as the context indicates.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed sequentially or separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a precursor or compound A, e.g. organic platinum group metal precursor) is pulsed into the reaction zone followed by a first time delay. Next, a second precursor or compound B (e.g. reductant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B, and purge gas is a cycle. A cycle can start with either compound A or compound B and continue the respective order of the cycle until achieving a film with the predetermined thickness.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein “metal carbide” and “metal carbide film” refer to a film that comprises a metal and carbon. When carbon and an element, which is of lesser electronegativity than carbon (e.g. a transition metal), combine to form a compound, that compound is known as a carbide. In metal carbides, multiple stoichiometries are common (e.g. iron forms a number of carbides—Fe₃C, Fe₇C₃, Fe₂C). Without intending to be bound by theory, it is thought that the desired amount of metal and carbon, on an atomic basis, in the metal carbide film, or in the mixed-metal carbide film, depends upon the work function of the film. In one or more embodiments, the metal carbide film and/or the mixed-metal carbide film contains greater than about 20% carbon (C) on an atomic basis, including greater than about 25%, greater than about 30%, greater than about 35%, greater than about 40%, greater than about 45%, or greater than about 50%. In one or more embodiments, the metal carbide film and/or the mixed-metal carbide film contains less than about 50% total metal content on an atomic basis, including less than about 45% total metal, less than about 40% total metal, less than about 35% total metal, or less than about 30% total metal. In other embodiments, the metal carbide film contains less than about 90% total metal content on an atomic basis, including less than about 85% total metal, less than about 80% total metal, less than about 75% total metal, less than about 70% total metal, less than about 65% total metal, less than about 60% total metal, less than about 55% total metal, less than about 50% total metal, less than about 40% total metal, less than about 35% total metal, or less than about 30% total metal. As used herein, the term “total metal content” refers to the percentage of metal, on an atomic basis, present in the metal carbide film and/or the mixed-metal carbide film. The metal may come from the first halide precursor, the aluminum reactant, and the additional halide precursors, if present.

One or more embodiments of the disclosure are directed to methods that use halide precursors of formula (I)

MX_{y}Rₙ (I)

wherein M is a metal, X is a halogen selected from Cl, Br, F, or I, y is from 1 to 6, R is selected from alkyl, CO, cyclopentadienyl, amidinate, diazadiene, or amidate, and n is from 0 to 6.

In one or more embodiments, the metal, M, is selected from one or more metal from group III, group IV, group V, group VI, or group VII of the periodic table, or Sn or Si. In other embodiments, the metal, M, is selected from one or more of scandium (Sc), yttrium (Y), lanthanum (La), actinium (Ac), titanium (Ti), zirconium (Zr), hafnium (Hf), vanadium (V), niobium (Nb), tantalum (Ta), chromium (Cr), molybdenum (Mo), tungsten (W), manganese (Mn), rhenium (Re), technetium (Tc), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg), tin (Sn), or (silicon) Si. In one or more embodiments, the metal M is selected from one or more of Ti, Ta, Zr, La, Hf, Ce, Zn, Cr, Sn, W, or V. In one or more specific embodiment, the metal M is hafnium (Hf). In another specific embodiment, the metal M is tungsten (W). The metal M is not aluminum (Al).

In one or more embodiments, X is a halogen selected from Cl, Br, F, or I. In one or more embodiments, y is from 1 to 6, including 1, 2, 3, 4, 5, or 6. In other embodiments, X is selected from Cl or Br. In a specific embodiment, X is Cl. In another specific embodiment, X is Br.

As used herein, “alkyl,” or “alk” includes both straight and branched chain hydrocarbons, containing 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. In one or more embodiments, R is selected from alkyl, CO, cyclopentadienyl, amidinate, diazadiene, or amidate. In one or more embodiments, R is C₁₋₆ alkyl. In one or more embodiments, n is from 0 to 6, including 0, 1, 2, 3, 4, 5, or 6.

One or more embodiments of the disclosure are directed to processes that use alkyl aluminum precursors that do not have β-hydrogen (β-H) fragments, to increase thermal stability and reduce the potential for isomerization in the ampoule. Formula (II) is a general structure for an aluminum precursor with no p-hydrogen:

Al(CH₂AR¹R²R³)₃ (II)

or, structurally depicted as

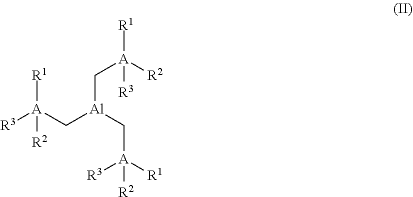

wherein each A independently comprises C, Si, or Ge, each of R¹, R², and R³ is independently an alkyl or comprises substantially no p-hydrogen. Each of R¹, R², and R³ in formula/structure (II) can have structural identities independent from any other R¹, R², and R³ group so that there can be in the range of 1 to 9 different R¹, R², and R³ groups. In one or more embodiments, each A does not contain a beta hydrogen.

Each of the A groups in the compound having the structure (II) can be independently C, Si, or Ge. In some embodiments, each of the A atoms is C. In some embodiments, each of the A atoms is Si. In some embodiments, each of the A atoms is Ge. In some embodiments, the A atoms are a mixture of two or more of C, Si, and Ge.

In some embodiments, each of R¹, R², and R³ is independently an alkyl. This means that each R¹, R², and R³ group is an alkyl group but each of the R¹, R², and R³ groups does not need to be the same alkyl group. In some embodiments, each of the R¹, R², and R³ groups are substantially the same species. As used in this specification and the appended claims, the term “substantially the same” used in this regard means that greater than about 95% of the R¹, R², and R³ groups are the same. In some embodiments, each of the R¹, R², and R³ groups is one of methyl and ethyl.

In one or more embodiments, as depicted in Scheme II, the first halide precursor of formula (I) is reacted with an alkyl aluminum reactant of formula (II) through a ligand exchange reaction. The halide X is transferred to aluminum (Al), and the alkyl group ((CH₂)AR¹R²R³) is transferred to the metal M. In general, alkyl metal compounds are unstable at high temperatures and can decompose to metal, and some carbon may be left as impurity. Halogenated alkyl aluminum species leave the surface of the substrate due to their volatility. If the aluminum (Al) compound is not stable at high temperatures, aluminum (Al) may incorporate into the film.

Without intending to be bound by theory, it is thought that one possible pathway to decompose an alkyl aluminum compound is p-hydride elimination. As shown in Scheme I, above, p-hydrogen can be transferred to the aluminum (Al) center, and the alkyl aluminum can decompose to leave Al in the growing film. If the β-hydrogen, however, is not present, as in one or more embodiments, then this pathway is not possible and the growing metal carbide film will not contain aluminum (Al).

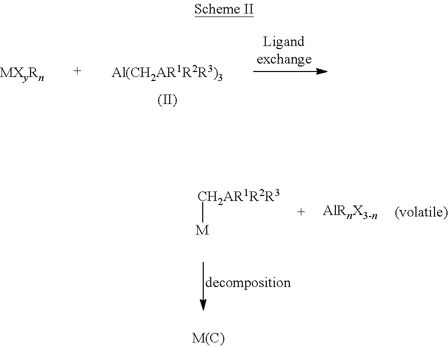

In some embodiments, the compound having the formula/structure (II) can be used as a reactant and the deposited film comprises substantially no metal (i.e. aluminum) from the reactant. For example, the final film comprises substantially no aluminum. As used in this specification and the appended claims, the term “substantially no” used in this regard means that there is less than about 5% on an atomic basis, including less than about 4%, less than about 3%, less than about 2%, or less than about 1%. In one or more embodiments, the metal carbide film is substantially free of aluminum (Al). As used in this regard, the term “substantially free of aluminum” means that the metal carbide film has less than about 10% aluminum (Al), on at atomic basis, including less than about 9%, less than about 8%, less about 7%, less than about 6%, less than about 5%, less than about 4%, less than about 3%, less than about 2%, or less than about 1%.

Some non-limiting examples of suitable compounds according to formula/structure (II) include

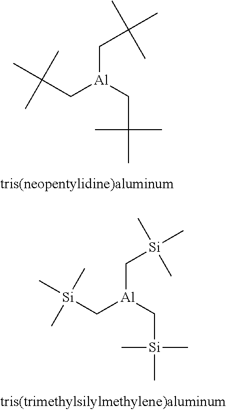

In one or more specific embodiments, the aluminum reactant is selected from one or more of tris(neopentylidine)aluminum (NPA) or tri(trimethylsilylmethylene)aluminum.

One or more embodiments of the disclosure are directed to methods of depositing a film. The method comprises exposing at least a portion of a substrate surface to a first halide precursor comprising a compound having the general formula (I). At least a portion of the substrate surface is then exposed to an aluminum reactant to deposit a metal carbide film on the substrate surface.

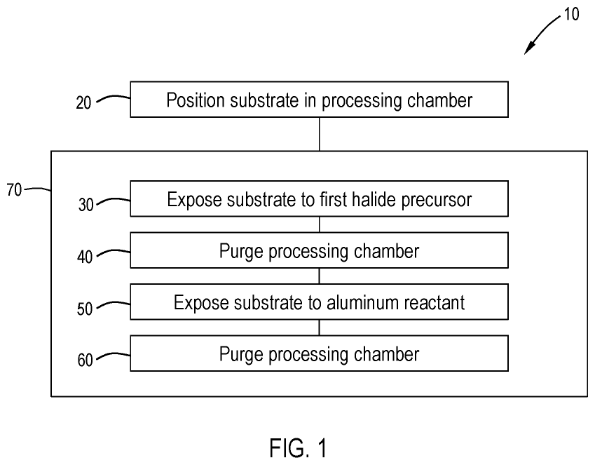

FIG. 1 depicts a flow diagram of a method 10 of depositing a metal carbide film in accordance with one or more embodiments of the present disclosure. With reference to FIG. 1, the method 10 comprises a deposition cycle 70. The method 10 begins at operation 20 by positioning a substrate into a processing chamber.

At operation 30, at least a portion of the substrate surface is exposed to a first halide precursor. The first halide precursor comprising a compound having the general formula (I)

MX_{y}Rₙ (I),

wherein M is a metal, X is a halogen selected from Cl, Br, F, or I, y is from 1 to 6, R is selected from alkyl, CO, cyclopentadienyl, amidinate, diazadiene, or amidate, and n is from 0 to 6.

The first halide precursor-containing process gas may be provided in one or more pulses or continuously. The flow rate of the first halide precursor-containing process gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. The first halide precursor of formula I can be provided at any suitable pressure including, but not limited to, a pressure in the range of about 5 mTorr to about 30 Torr, or in the range of about 100 mTorr to about 30 Torr, or in the range of about 5 Torr to about 30 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to the first halide precursor-containing process gas may be any suitable amount of time necessary to allow the precursor to form an adequate nucleation layer atop the conductive substrate surfaces. For example, the process gas may be flowed into the process chamber for a period of about 0.1 seconds to about 90 seconds. In some time-domain ALD processes, the first halide precursor-containing process gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert carrier gas may additionally be provided to the process chamber at the same time as the first halide precursor-containing process gas. The carrier gas may be mixed with the first halide precursor-containing process gas (e.g., as a diluent gas) or separately and can be pulsed or of a constant flow. In some embodiments, the carrier gas is flowed into the processing chamber at a constant flow in the range of about 1 to about 10000 sccm. The carrier gas may be any inert gas, for example, such as argon, nitrogen, helium, neon, combinations thereof, or the like. In one or more specific embodiments, the first halide precursor-containing process gas is mixed with argon prior to flowing into the process chamber.

The temperature of the substrate during deposition can be controlled, for example, by setting the temperature of the substrate support or susceptor. In some embodiments the conductive substrate is held at a temperature in a range of about 100° C. to about 500° C., including a temperature of about 100° C., about 150° C., about 200° C., about 250°, about 300° C., about 350° C., about 400° C., about 450° C., and about 500° C.

At operation 40, the processing chamber is then purged of the first halide precursor. Purging can be accomplished with any suitable gas that is not reactive with the substrate, film on the substrate, and/or processing chamber walls. Suitable purge gases include, but are not limited to, N₂, He, and Ar. The purge gas may be used to purge the processing chamber of the first halide precursor, and/or the aluminum reactant. In some embodiments, the same purge gas is used for each purging operation. In other embodiments, a different purge gas is used for the various purging operations.

At operation 50, at least a portion of the substrate surface is exposed to an aluminum reactant to deposit a metal carbide film. The aluminum reactant comprising a compound of general formula (II)

Al(CH₂AR¹R²R³)₃ (II)

wherein A is C, Si, or Ge, each of R¹, R², and R³ is independently alkyl or comprises substantially no β-hydrogen.

At operation 60, the processing chamber is then purged of the aluminum reactant.

The metal carbide film is deposited on the substrate surface. In one or more embodiments, the metal carbide film is substantially free of aluminum, and the metal carbide film has less than 50% total metal content on an atomic basis. In other embodiments, the metal carbide film is substantially free of aluminum, and the metal carbide film has less than 90% total metal content on an atomic basis.

Some embodiments of the disclosure further comprise exposing the substrate surface to a second halide precursor. The second precursor can be exposed to the substrate at the same time as the first halide precursor and/or the aluminum reactant, or at a separate time from either or both. For example, the first halide precursor may be a compound of general formula (I) and the second halide precursor may have the same general formula (I) with a different metal M than the first halide precursor. Mixed metal carbide films can be formed by using different first and second halide precursors. Thus, in one or more embodiments, the method is repeated (i.e. process cycle 70 is repeated) to provide a metal carbide film comprising more than one metal M. In such cases, however, the metal carbide film comprises less than about 50% total metal content on an atomic basis.

In one or more embodiments, to produce mixed-metal carbide films, a cycle of M¹-carbide (i.e. the first metal, M¹) is carried out, then a cycle of M²-carbide (i.e. the second metal, M²) is carried out. This sequence can be repeated to achieve the desired mixed-metal carbide film thickness. Without intending to be bound by theory, it is thought that changing the ratio of M¹-carbide cycles to M²-carbide cycles, different ratios of M¹ and M² can be archived. In one or more embodiments, the metal M¹ and the metal M² are independently selected from one or more metal from group III, group IV, group V, group VI, or group VII of the periodic table, or Sn or Si. In other embodiments, the metal M¹ and the metal M² are independently selected from one or more of scandium (Sc), yttrium (Y), lanthanum (La), actinium (Ac), titanium (Ti), zirconium (Zr), hafnium (Hf), vanadium (V), niobium (Nb), tantalum (Ta), chromium (Cr), molybdenum (Mo), tungsten (W), manganese (Mn), rhenium (Re), technetium (Tc), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg), tin (Sn), or (silicon) Si. In one or more embodiments, the metal M¹ and the metal M² are independently selected from one or more of Ti, Ta, Zr, La, Hf, Ce, Zn, Cr, Sn, W, or V.

One or more embodiments are directed to a method of depositing a film, the method comprising exposing at least a portion of a substrate surface to a first halide precursor comprising a compound having the general formula (IA)

M¹X_{y}Rₙ (IA),

wherein M¹ is a metal, X is a halogen selected from Cl, Br, F or I, y is from 1 to 6, R is selected from alkyl, CO, cyclopentadienyl, amidinate, diazadiene, or amidate, and n is from 0 to 6. At least a portion of the substrate surface is then exposed to a second halide precursor comprising a compound having the general formula (IB)

M²X_{y}Rₙ (_{IB}),

wherein M² is a metal, X is a halogen selected from Cl, Br, F or I, y is from 1 to 6, R is selected from alkyl, CO, cyclopentadienyl, amidinate, diazadiene, or amidate, and n is from 0 to 6. At least a portion of the substrate surface is then exposed to an aluminum reactant comprising a compound of general formula (II)

Al(CH₂AR¹R²R³)₃ (II)

wherein A is C, Si, or Ge, each of R¹, R², and R³ is independently alkyl or comprises substantially no p-hydrogen. A mixed-metal carbide film is deposited on the substrate surface, the mixed-metal carbide film substantially free of aluminum.

Depending upon the different metal(s) desired in the mixed-metal carbide film, the substrate surface can be exposed to many different cycles of halide precursors having a general formula (IP): M^{P}X_{y}Rₙ (IP), wherein P is an integer in a range of 1 to 100, or 1 to 1000, or 1 to greater than 1000. M^{P} is a metal, X is a halogen selected from Cl, Br, F or I, y is from 1 to 6, R is selected from alkyl, CO, cyclopentadienyl, amidinate, diazadiene, or amidate, and n is from 0 to 6.

For example, in one or more specific embodiments, the first halide precursor may comprises hafnium (Hf) as metal M and the aluminum reactant may comprise tris(neopentylidine)aluminum (NPA)) to deposit a hafnium carbide (HfC) film, substantially free of aluminum, and having less than about 50% total metal content on an atomic basis. In other specific embodiments, the first halide precursor may comprises hafnium (Hf) as metal M¹, the aluminum reactant may comprise tris(neopentylidine)aluminum (NPA), and the second halide precursor may comprise titanium (Ti) as metal M² to deposit a mixed metal carbide film; the mixed metal carbide film comprising hafnium titanium carbide (HfTiC), substantially free of aluminum, and having less than about 50% total metal content on an atomic basis. In still further embodiments, the first halide precursor may comprise hafnium (Hf) as metal M¹, the second halide precursor may comprise titanium (Ti) as metal M², a third halide precursor may comprise silicon (Si) as metal M³, and the aluminum reactant comprises aluminum to deposit a mixed metal carbide film comprising hafnium titanium silicon carbide (HfTiSiC), substantially free of aluminum, and having less than about 50% total metal content on an atomic basis. In yet further embodiments, the first halide precursor may comprise hafnium (Hf) as metal M¹, the second halide precursor may comprise titanium (Ti) as metal M², the third halide precursor may comprise silicon (Si) as metal M³, a fourth halide precursor may comprise tantalum (Ta) as metal M⁴, and the aluminum reactant comprises aluminum to deposit a mixed metal carbide film comprising hafnium titanium silicon tantalum carbide (HfTiSiTaC), substantially free of aluminum, and having less than about 50% total metal content on an atomic basis.

In some embodiments, exposing the substrate surface to the first halide precursor and the aluminum reactant occurs sequentially. For example, an ALD type process so that the substrate surface (or portion thereof) is exposed to the first halide precursor and the aluminum reactant sequentially or substantially sequentially. In some embodiments, exposing the substrate surface to the first halide precursor and the aluminum reactant occurs simultaneously. For example, a CVD type process in which both the first halide precursor and the aluminum reactant are flowed into the processing chamber at the same time, allowing gas phase reactions of the precursor and the reactant.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific portions of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

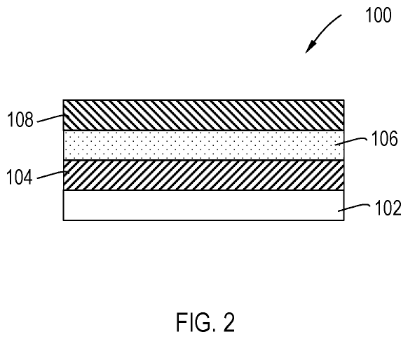

One or more embodiments of the disclosure are directed to a metal oxide stack that is part of a gate stack in a metal oxide semiconductor (MOS). Referring to FIG. 2, the metal oxide stack 100 comprises a high-κ dielectric layer 104 on a substrate 102, and a titanium nitride layer 106 on the high-κ dielectric layer 104. The embodiment illustrated in FIG. 2 has a separate high-κ dielectric layer 104 on a substrate 102. However, the skilled artisan will recognize that the high-κ dielectric layer 104 can be the substrate 102 or a portion of the substrate 102. For example, the high-κ dielectric 104 can be formed on the substrate 102 to form the metal oxide stack 100.

The metal oxide stack 100 is formed on substrate 102 which can be any suitable material or shape. In the embodiment illustrated, the substrate 102 is a flat surface and the metal oxide stack 100 is represented by rectangular boxes placed on top of one another. However, those skilled in the art will understand that the substrate 102 can have one or more features (i.e., trenches or vias) and that the metal oxide stack 100 can be formed to conform to the shape of the substrate 102 surface.

A work function layer 108 is formed on the titanium nitride layer 106. In one or more embodiments, the work function layer 108 comprises a metal carbide film that is substantially free of aluminum and has less than 50% total metal content on an atomic basis. The metal carbide film is prepared by the methods of one or more embodiments. The metal carbide film can be formed by exposing at least a portion of the substrate 102 to a first halide precursor comprising a compound having the general formula (I)

MX_{y}Rₙ (I),

wherein M is a metal, X is a halogen selected from Cl, Br, F or I, y is from 1 to 6, R is selected from alkyl, CO, cyclopentadienyl, amidinate, diazadiene, or amidate, and n is from 0 to 6; and exposing at least a portion of the substrate 102 to an aluminum reactant comprising a compound of general formula (II)

Al(CH₂AR¹R²R³)₃ (II)

wherein A is C, Si, or Ge, each of R¹, R², and R³ is independently alkyl or comprises substantially no β-hydrogen, to deposit a metal carbide film as a work function layer 108 on the substrate 102, the metal carbide film substantially free of aluminum.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1

### Comparative

Hafnium tetrachloride (HfCl₄) and tritertbutylalumium (TTBA) were employed in ALD fashion to deposit hafnium carbide (HfC) films. A silicon substrate was heated to 300° C. in an ALD chamber. Hafnium tetrachloride (HfCl₄), which was in an ampoule, was heated to 145° C. and pulsed to the chamber for 10 seconds followed by a 10 second nitrogen purge. Then a 5 second tritertbutylalumium (TTBA) pulse was given from a TTBA ampoule, which was at room temperature, followed by a 10 second nitrogen purge. The above mentioned cycle was repeated to get the desired thickness hafnium carbide (HfC) film. TTBA contains p-hydrogen. The resulting hafnium carbide film contained aluminum. Additionally, the hafnium carbide film (HfC) was rough in appearance when viewed by SEM.

Table 1 shows the elemental percentages of the hafnium carbide film of Example 1. The film contains greater than 50% total metal on an atomic basis. The amount of hafnium and aluminum present totals 57.1%.

| Element | Atomic % |
|---|---|
| Aluminum (Al) | 20.1 |
| Hafnium (Hf) | 37.0 |
| Carbon (C) | 27.4 |
| Other Elements | 15.4 |

### Example 2

Hafnium tetrachloride (HfCl₄) and trineopentylaluminum (NPA) were employed in ALD fashion as described to deposit hafnium carbide (HfC) films. A silicon substrate was heated to 300° C. in an ALD chamber. Hafnium tetrachloride (HfCl₄), which was in an ampoule, was heated to 145° C. and pulsed to the chamber for 10 seconds followed by a 10 second nitrogen purge. Then a 5 second trineopentylaluminum (NPA) pulse was given from a NPA ampoule, which was at room temperature, followed by a 10 second nitrogen purge. The above mentioned cycle was repeated to get the desired thickness harfnium carbide (HfC) film. NPA does not have p-hydrogen. The hafnium carbide film was substantially free of aluminum. The HfC film was smooth when viewed by SEM.

Table 2 shows the elemental percentages of the hafnium carbide film of Example 2. The film contains less than 50% total metal content on an atomic basis. The amount of hafnium and aluminum present totals 42.1%.

| Element | Atomic % |
|---|---|
| Aluminum (Al) | 0.1 |
| Hafnium (Hf) | 42.0 |
| Carbon (C) | 28.4 |
| Other Elements | 29.3 |

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in some embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a film, the method comprising:
exposing at least a portion of a substrate surface to a first halide precursor comprising a compound having the general formula (I)
MX_{y}Rₙ (I),
wherein M is a metal, X is a halogen selected from Cl, Br, F or I, y is from 1 to 6, R is selected from alkyl, CO, cyclopentadienyl, amidinate, diazadiene, or amidate, and n is from 0 to 6; and
exposing at least a portion of the substrate surface to an aluminum reactant comprising a compound of general formula (II)
Al(CH₂AR¹R²R³)₃ (II)
wherein A is C, Si, or Ge, each of R¹, R², and R³ is independently alkyl or comprises substantially no β-hydrogen,
to deposit a metal carbide film on the substrate surface, the metal carbide film substantially free of aluminum.

2. The method of claim 1, wherein M is selected from one or more of Sc, Y, La, Ac, Ti, Zr, Hf, V, Nb, Ta, Cr, Mo, W, Mn, Re, Tc, Fe, Ru, Os, Co, Rh, Ir, Ni, Pd, Pt, Cu, Ag, Au, Zn, Cd, Hg, Sn, or Si.

3. The method of claim 2, wherein M is Hf.

4. The method of claim 1, wherein X is Cl or Br.

5. The method of claim 1, wherein X is Cl.

6. The method of claim 1, wherein X is Br.

7. The method of claim 1, wherein R is a C₁₋₆ alkyl.

8. The method of claim 1, wherein exposing the substrate surface to the first halide precursor and the aluminum reactant occurs sequentially.

9. The method of claim 1, wherein exposing the substrate surface to the first halide precursor and the aluminum reactant occurs simultaneously.

10. The method of claim 1, wherein the aluminum reactant is selected from one or more or tris(neopentylidine)aluminum (NPA) or tri(trimethylsilylmethylene)aluminum.

11. The method of claim 1, further comprising repeating the method to provide a metal carbide film comprising more than one metal M.

12. A method of depositing a film, the method comprising:
exposing at least a portion of a substrate surface to a first halide precursor comprising a compound having the general formula (IA)
M¹X_{y}Rₙ (IA),
wherein M¹ is a metal, X is a halogen selected from Cl, Br, F or I, y is from 1 to 6, R is selected from alkyl, CO, cyclopentadienyl, amidinate, diazadiene, or amidate, and n is from 0 to 6;
exposing at least a portion of the substrate surface to a second halide precursor comprising a compound having the general formula (IB)
M²X_{y}Rₙ (IB),
wherein M² is a metal, X is a halogen selected from Cl, Br, F or I, y is from 1 to 6, R is selected from alkyl, CO, cyclopentadienyl, amidinate, diazadiene, or amidate, and n is from 0 to 6; and
exposing at least a portion of the substrate surface to an aluminum reactant comprising a compound of general formula (II)
Al(CH₂AR¹R²R³)₃ (II)
wherein A is C, Si, or Ge, each of R¹, R², and R³ is independently alkyl or comprises substantially no β-hydrogen,
to deposit a mixed-metal carbide film on the substrate surface, the mixed-metal carbide film substantially free of aluminum.

13. The method of claim 12, further comprising exposing at least a portion of the substrate surface to a third halide precursor prior to exposing the substrate surface to the aluminum reactant, the third halide precursor comprising a compound having the general formula (IC)
M³X_{y}Rₙ (IC),
wherein M³ is a metal, X is a halogen selected from Cl, Br, F or I, y is from 1 to 6, R is selected from alkyl, CO, cyclopentadienyl, amidinate, diazadiene, or amidate, and n is from 0 to 6.

14. The method of claim 12, wherein M¹, M², and M³ are independently selected from Sc, Y, La, Ac, Ti, Zr, Hf, V, Nb, Ta, Cr, Mo, W, Mn, Re, Tc, Fe, Ru, Os, Co, Rh, Ir, Ni, Pd, Pt, Cu, Ag, Au, Zn, Cd, Hg, Sn, or Si.

15. The method of claim 12, wherein M is Hf.

16. The method of any one of claims 12, wherein X is Cl or Br.

17. The method of claim 12, wherein X is Cl.

18. The method of claim 12, wherein X is Br.

19. The method of any one of claims 12, wherein R is a C₁₋₆ alkyl.

20. A gate stack comprising:
a high-κ dielectric layer on a substrate;
a first titanium nitride layer on the high-κ dielectric layer;
a work-function layer on the first titanium nitride layer; and
a second titanium nitride layer on the work-function layer,
wherein the function layer comprises a metal carbide film substantially free of aluminum and having less than 50% total metal content on an atomic basis.
